(19) United States
(12) Patent Application Publication
(10) Pub. No.: US 2021/0111376 A1
(43) Pub. Date: Apr. 15, 2021

(54) BOTH-SIDE LIGHT EMITTING LIGHTING DEVICE

(71) Applicant: CHEOMDANLAB INC., Gwangju (KR)

(72) Inventors: Ha Jun JANG, Gwangju (KR); Yun Jeong PARK, Gwangju (KR); Kyung Im SHIN, Gwangju (KR)

(73) Assignee: CHEOMDANLAB INC., Gwangju (KR)

(21) Appl. No.: 17/057,823

(22) PCT Filed: Dec. 5, 2018
(86) PCT No.: PCT/KR2018/015294

§ 371 Date: Nov. 23, 2020

(30) Foreign Application Priority Data
Nov. 26, 2018 (KR) 10-2018-0147695

(51) Int. Cl. H01L 51/52; H01L 33/58

(52) U.S. Cl. CPC H01L 51/5268; H01L 33/58

(57) ABSTRACT

The present application relates to a both-side light-emitting lighting device, which maximizes a scattering effect so as to be capable of increasing light extraction efficiency, and may acquire high power efficiency as a both-side light-emitting lighting device so as to be capable of increasing the lifespan of the lighting device, and includes: a first light-outputting surface; a second light-outputting surface positioned to face the first light-outputting surface; a light-emitting device positioned between the first light-outputting surface and the second light-outputting surface; and a light extraction film including a base material, which is positioned on the first light-outputting surface, has first and second surfaces facing each other, and is provided such that light enters through the first surface and exits through the second surface, and a plurality of pores irregularly distributed in the base material, wherein the base material allows the light to be scattered when the light transmits therethrough, the scattering includes first scattering by the pores and second scattering by the first surface and/or the second surface, and the base material is provided such that a first scattering degree caused by the first scattering relatively differs from a second scattering degree caused by the second scattering.

### TECHNICAL FIELD

One or more embodiments relate to a both-side light-emitting lighting device.

### BACKGROUND ART

A self-emissive device such as an organic light-emitting device may be used as a surface-emitting lighting device. However, light generated from an emission layer has to go through a lot of interfaces before it is emitted from a light extraction surface, and thus, there may be a lot of light loss and a light extraction efficiency may degrade. Such degradation in the light extraction efficiency increases power consumption, which causes reduction in lifespan of a lighting device.

Also, the lighting device may emit light through both of front and rear surfaces thereof, and it may be difficult to adjust luminance in each of front and rear surface directions.

### DESCRIPTION OF EMBODIMENTS

### Technical Problem

In order to address an issue of degrading a light extraction efficiency in a both-side light-emitting lighting device, there is provided a both-side light-emitting lighting device having high light extraction efficiency and improved power efficiency.

Also, luminance of the light emitted in both-side directions may be adjusted in a simple way.

### Solution to Problem

In order to achieve the purpose of the invention, according to an embodiment of the present invention includes a both-side light-emitting lighting device including a first light-outputting surface; a second light-outputting surface facing the first light-outputting surface; a light-emitting device located between the first light-outputting surface and the second light-outputting surface, emitting first light in a direction toward the first light-outputting surface, and emitting second light in a direction toward the second light-outputting surface; and a light extraction film located on the first light-outputting surface and including a base material having a first surface and a second surface facing each other so that the first light enters through the first surface and exits through the second surface, and a plurality of pores irregularly distributed in the base material, wherein the base material scatters the first light transmitting through the base material, scattering of the light comprises a first scattering caused by pore particles and a second scattering caused by at least one of the first surface and the second surface, and the base material is provided such that a first scattering degree due to the first scattering and a second scattering degree due to the second scattering are different relative to each other.

When the first scattering degree due to the first scattering is greater than the second scattering degree due to the second scattering, a light transmittance of the base material may be 70% or greater.

When the second scattering degree due to the second scattering is greater than the first scattering degree due to the first scattering, a light transmittance of the base material may be less than 70%.

When the first scattering degree due to the first scattering is greater than the second scattering degree due to the second scattering, a light reflectivity of the base material may be less than 20%.

When the second scattering degree due to the second scattering is greater than the first scattering degree due to the first scattering, a light reflectivity of the base material may be 20% or greater.

When the first scattering degree due to the first scattering is greater than the second scattering degree due to the second scattering, the pores may each have a first diameter, when the second scattering degree due to the second scattering is greater than the first scattering due to the first scattering, the pores may each have a second diameter, and the first diameter may be greater than the second diameter.

When the first scattering degree due to the first scattering is greater than the second scattering degree due to the second scattering, at least one of the first surface and the second surface may have a first roughness, when the second scattering degree due to the second scattering is greater than the first scattering degree due to the first scattering, at least one of the first surface and the second surface may have a second roughness, and the second roughness may be greater than the first roughness.

### Advantageous Effects of Disclosure

According to one or more embodiments of the present invention, a light extraction efficiency may be improved.

High power efficiency may be obtained by using the both-side light-emitting lighting device, and accordingly, lifespan of the both-side light-emitting lighting device may be improved.

The luminance in both directions may be simply adjusted.

The both-side light-emitting lighting device according to the present invention may be used in a transparent lighting device through which external light may transmit. In this case, the light-emitting efficiency and luminance adjustment in both directions may be achieved, and thus, lighting effect may be further improved.

### BRIEF DESCRIPTION OF DRAWINGS

FIG. 1 is a schematic cross-sectional view of a light extraction film according to an embodiment.

FIG. 2 is a schematic cross-sectional view of a light extraction film according to another embodiment.

FIG. 3 is a schematic cross-sectional view of a both-side light-emitting lighting device according to another embodiment.

FIG. 4 is a schematic cross-sectional view of a both-side light-emitting lighting device according to another embodiment.

FIG. 5 is a cross-sectional view partially showing an organic light-emitting unit according to an embodiment.

FIG. 6 shows a cross-sectional scanning electron microscope (SEM) photograph (a) and a surface SEM photograph (b) in a first embodiment.

FIG. 7 shows a cross-sectional SEM photograph (a) and a surface SEM photograph (b) in a second embodiment.

FIG. 8 shows a total transmittance according to a wavelength band of a visible ray area in the first embodiment (A) and the second embodiment (B).

FIG. 9 shows an optical haze value according to a wavelength band of a visible ray area in the first embodiment (A) and the second embodiment (B).

FIG. 10 shows a comparison among power efficiencies of the both-side light-emitting lighting devices on which the first embodiment (A) and the second embodiment (B) are formed, and of a comparative example (ref).

FIG. 11 shows power efficiencies in the first embodiment (A), the second embodiment (B), and a comparative example (ref).

FIG. 12 is a diagram showing a change in a luminance in a first direction according to a current change in the first embodiment (A), the second embodiment (B), and the comparative example (ref).

FIG. 13 is a diagram showing a change in a luminance in a second direction according to a current change in the first embodiment (A), the second embodiment (B), and the comparative example (ref).

### MODE OF DISCLOSURE

As the present invention allows for various changes and numerous embodiments, particular embodiments will be illustrated in the drawings and described in detail in the written description. The attached drawings for illustrating one or more embodiments are referred to in order to gain a sufficient understanding, the merits thereof, and the objectives accomplished by the implementation. However, the embodiments may have different forms and should not be construed as being limited to the descriptions set forth herein.

The embodiments will be described below in more detail with reference to the accompanying drawings. Those components that are the same or are in correspondence are rendered the same reference numeral regardless of the figure number, and redundant explanations are omitted.

An expression used in the singular encompasses the expression of the plural, unless it has a clearly different meaning in the context.

In the present specification, it is to be understood that the terms “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It will be understood that when a layer, region, or component is referred to as being “formed on” another layer, region, or component, it may be directly or indirectly formed on the other layer, region, or component. That is, for example, intervening layers, regions, or components may be present.

When a certain embodiment may be implemented differently, a specific process order may be performed differently from the described order. For example, two consecutively described processes may be performed substantially at the same time or performed in an order opposite to the described order.

Sizes of components in the drawings may be exaggerated for convenience of explanation. In other words, since sizes and thicknesses of components in the drawings are arbitrarily illustrated for convenience of explanation, the following embodiments are not limited thereto.

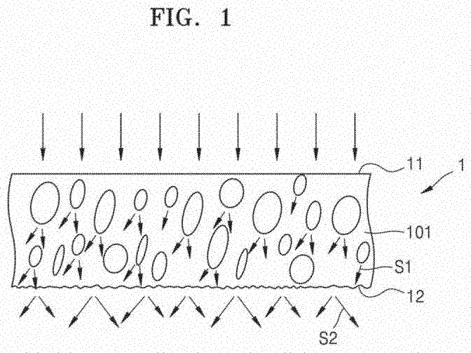

FIG. 1 is a schematic cross-sectional view of a light extraction film 1 according to an embodiment.

Referring to FIG. 1, the light extraction film 1 according to an embodiment of the present invention may include a base material 101, and a plurality of pores 102 irregularly distributed in the base material 101.

The base material 101 may include a light-transmitting polymer material, e.g., polyimide according to an embodiment. The base material 101 may be flexible.

The base material 101 include a first surface 11 and a second surface 12 facing each other, wherein the first surface 11 may be an incident surface into which light is incident and the second surface 12 may be an exit surface from which light is emitted. Therefore, the light may be incident into the base material 101 via the first surface 11 and may be emitted through the second surface 12.

The plurality of pores 102 may be irregularly distributed between the first surface 11 and the second surface 12 of the base material 101. The pores 102 may act as light scattering particles, may each form a hollow cavity, and may have a refractive index of air in the space.

The base material 101 as above may scatter the light when the light transmits through the base material 101.

The scattering may include a first scattering S1 caused by the pores 102, and a second scattering S2 caused by at least one of the first surface 11 and the second surface 12.

The light transmitting through the base material 101 collides with the pores 102 that are irregularly arranged in an optical path thereof, and is scattered due to a difference between refractive indices of the air in the pores 102 and the polymer in the base material 101. The first scattering S1 may include Mie scattering. The first scattering S1 may scatter most of the light in the form of spreading in the proceeding direction of the light.

In addition, the light transmitting through the base material 101 may be scattered (second scattering S2) by at least one of the first surface 11, that is, the incident surface, and the second surface 12, that is, the exit surface. According to an embodiment, the second scattering S2 may include the scattering caused by the second surface 12. The second scattering S2 may include surface scattering. According to the second scattering S2, the scattered light may not only spread in the proceeding direction of the light, but in other directions than the proceeding direction, that is, in a lateral direction and/or a rear direction.

The light extraction film 1 according to the embodiment may be configured so that a first scattering degree due to the first scattering S1 and a second scattering degree due to the second scattering S2 may be different relative to each other. That is, the light extraction film 1 according to the embodiment may be configured so that the first scattering degree due to the first scattering S1 may be greater than the second scattering degree due to the second scattering S2 according to required optical characteristics. That is, the light extraction film 1 according to another embodiment may be configured such that the second scattering degree due to the second scattering S2 may be greater than the first scattering degree due to the first scattering S1 according to required optical characteristics.

According to an embodiment, in the light extraction film 1, when the first scattering degree due to the first scattering S1 is greater than the second scattering degree due to the second scattering S2, an average total transmittance of the base material 101, that is, the light extraction film 1, with respect to the wavelength of the light may be 70% or greater. Here, an average total reflectivity of the base material 101 with respect to the wavelength of the light may be less than 20%. The average total transmittance with respect to the wavelength of the light may correspond to an average value of a total integral transmittance that appears when the wavelength of the light is changed. The average total reflectivity with respect to the wavelength of the light may correspond to an average value of a total integral reflectivity that appears when the wavelength of the light is changed.

As described above, in the light extraction film 1, when the first scattering degree due to the first scattering S1 is greater than the second scattering degree of the second scattering S2, the light extraction film 1 having high transparency and low reflectivity may be obtained. In addition, an average light haze value with respect to the wavelength of the light may be about 80% or greater, and thus, high degree of haze may be exhibited, and a change in the luminance according to the viewing angle may be minimized and thereby achieving Lambertian emission. Moreover, a change in a color coordinate according to the viewing angle may be minimized. Also, when the light extraction film 1 is attached to the lighting device, the light extraction efficiency of the lighting device may be improved, a user may obtain a uniform white lighting effect, and excellent power efficiency may be achieved.

According to another embodiment, in the light extraction film 1, when the second scattering degree due to the second scattering S2 is greater than the first scattering degree due to the first scattering S1, an average total transmittance of the base material 101, that is, the light extraction film 1, with respect to the wavelength of the light may be less than 70%. Here, an average total reflectivity of the base material 101 with respect to the wavelength of the light may be equal to or greater than 20%.

As described above, in the light extraction film 1, when the second scattering degree due to the second scattering S2 is greater than the first scattering degree due to the first scattering S1, the transparency is relatively low and the reflectivity is relatively high, but an average light haze value with respect to the wavelength of the light may be about 80% or greater, and thus, a high haze degree may be exhibited. Also, the change in the luminance according to the viewing angle may be reduced, and thus, similar effects to those of the Lambertian emission may be obtained, and a change in the color coordinate according to the viewing angle may be reduced. Therefore, when the light extraction film 1 is attached to the lighting device, the light extraction efficiency of the lighting device may be improved, a user may obtain a uniform white lighting effect, and excellent power efficiency may be achieved.

When the first scattering degree due to the first scattering S1 is greater than the second scattering degree due to the second scattering S2, the light haze value of the light extraction film 1 is reduced to a first angle as the wavelength of the light increases, and when the second scattering degree due to the second scattering S2 is greater than the first scattering degree due to the first scattering S1, the light haze value of the light extraction film 1 may be reduced to a second angle as the wavelength of the light increases. Here, the second angle may be greater than the first angle. Therefore, with respect to the average light haze value according to the wavelength of the light, the light extraction film 1 when the first scattering degree due to the first scattering S1 is greater than the second scattering degree due to the second scattering S2 is greater than the light extraction film 1 when the second scattering degree due to the second scattering S2 is greater than the first scattering degree due to the first scattering S1. That is, in view of the light haze, the light extraction film 1 when the first scattering degree due to the first scattering S1 is greater than the second scattering degree due to the second scattering S2 may exhibit superior characteristics as compared with the light extraction film 1 when the second scattering degree due to the second scattering S2 is greater than the first scattering degree due to the first scattering S1. However, as described above, in the light extraction film 1 when the first scattering degree is greater than the second scattering degree due to the second scattering S2, a light haze value that is enough to be used in the lighting device may be obtained, and the change in luminance and the change in the color coordinate according to the angle may be reduced, and thus, optical characteristics as a lighting device may be exhibited.

In the light extraction film 1 according to the embodiment, when it is assumed that the pores 102 each have a first diameter when the first scattering degree due to the first scattering S1 is greater than the second scattering degree due to the second scattering S2, and the pores 102 each have a second diameter when the second scattering degree due to the second scattering S2 is greater than the first scattering degree due to the first scattering S1, the first diameter may be greater than the second diameter.

In the light extraction film 1 according to another embodiment, a surface roughness of at least one of the first surface 11 and the second surface 12 has a first roughness when the first scattering degree due to the first scattering S1 is greater than the second scattering degree due to the second scattering S2, and the surface roughness of at least one of the first surface 11 and the second surface 12 has a second roughness when the second scattering degree due to the second scattering S2 is greater than the first scattering degree due to the first scattering S1. Here, the second roughness may be greater than the first roughness.

When the first scattering degree due to the first scattering S1 is greater than the second scattering degree due to the second scattering S2, sizes of the pores 102 may largely affect the first scattering S1.

According to an embodiment, when the first scattering degree due to the first scattering S1 is greater than the second scattering degree due to the second scattering S2, the pores 102 may each have a radius of 0.5 μm or greater. Here, the radius of each of the pores 102 may be based on a longer axis. In more detail, the pores 102 may each have a radius of 1 μm or greater.

Selectively, the surface roughness of at least one of the first surface 11 and the second surface 12 may be 20 nm or less based on rms.

As described above, when the first scattering degree due to the first scattering S1 is greater than the second scattering degree due to the second scattering S2, the surface roughness of at least one of the first surface 11 and the second surface 12 may not largely affect the optical characteristics of the light extraction film 1. Therefore, in the light extraction film 1 according to the embodiment, when it is designed so that the first scattering degree due to the first scattering S1 is greater than the second scattering degree due to the second scattering S2, the pores 102 may be designed to each have a radius of 0.5 μm or greater.

In the light extraction film 1 according to another embodiment, when the second scattering degree due to the second scattering S2 is greater than the first scattering degree due to the first scattering S1, the surface roughness of at least one of the first surface 11 and the second surface 12 may largely affect the first scattering S1.

Selectively, when the first scattering degree due to the first scattering S1 is greater than the second scattering degree due to the second scattering S2, the surface roughness of at least one of the first surface 11 and the second surface 12 may be 50 nm or greater based on rms.

Selectively, the pores 102 may each have a radius of 1 μm or less. In detail, the pores 102 may each have a radius of 0.5 μm or less.

As described above, when the second scattering degree due to the second scattering S2 is greater than the first scattering degree due to the first scattering S1, the size of the pores 102 may less affect the optical characteristics of the light extraction film 1 as compared with the above-described embodiment.

Therefore, in the light extraction film 1 according to the embodiment, when it is designed so that the second scattering degree due to the second scattering S2 is greater than the first scattering degree due to the first scattering S1, the surface roughness of at least one of the first surface 11 and the second surface 12 may be designed to be 50 nm or greater based on rms.

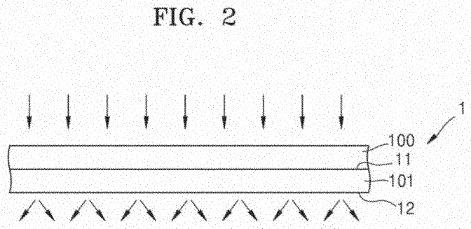

The light extraction film 1 according to the above-described embodiments may have a single film shape as shown in FIG. 1. However, one or more embodiments are not limited thereto, that is, the light extraction film 1 according to another embodiment may further include a base 100 adjacent to the first surface 11 as shown in FIG. 2. The base 100 may function as a support for forming the base material 101 in the manufacturing process of the base material 101. The base 100 may have a substrate and/or a film shape, may be rigid or flexible, and may include a glass material or a polymer material that may transmit light.

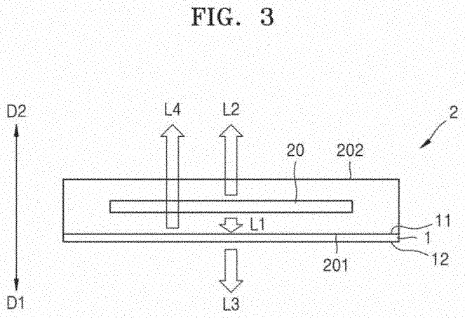

FIG. 3 is a schematic cross-sectional view of a both-side light-emitting lighting device 2 according to another embodiment.

Referring to FIG. 3, the both-side light-emitting lighting device 2 according to the embodiment may include a first light-outputting surface 201 and a second light-outputting surface 202 facing each other, a light-emitting device 20 located between the first light-outputting surface 201 and the second light-outputting surface 202, and the light extraction film 1 located on the first light-outputting surface 201.

The light-emitting device 20 may be located and encapsulated between the first light-outputting surface 201 and the second light-outputting surface 202 facing each other, and may emit first light L1 in a first direction D1 in which the first light-outputting surface 201 is located and emit second light L2 in a second direction D2 in which the second light-outputting surface 202 is located.

Because the first light-outputting surface 201 and the second light-outputting surface 202 face each other, the first light L1 and the second light L2 may emit in opposite directions to each other.

The light-emitting device 20 may be a self-emissive device, and according to an embodiment, the light-emitting device 20 may be an organic light-emitting device. However, one or more embodiments are not limited thereto, that is, the light-emitting device 20 may be an inorganic light-emitting device or may include various both-side light-emitting devices such as various UV LEDs, etc.

The light extraction film 1 may be located on the first light-outputting surface 201.

Therefore, the first light L1 is diffused while passing through the light extraction film 1, and accordingly, the first light L1 may become diffused third light L3. The third light L3 is obtained by diffusing the first light L1, and thus may have an improved luminance as compared with the first light L1.

The first light L1 may be reflected by the light extraction film 1, and the reflected first light L1 proceeds in the second direction D2 to form fourth light L4.

As described above, the light extraction film 1 may allow the transmittance and the reflectivity to be changed by adjusting a difference between the first scattering degree due to the first scattering and the second scattering degree due to the second scattering.

When the first scattering degree due to the first scattering is greater than the second scattering degree due to the second scattering, the light transmittance of the light extraction film 1 may be greater than that of the light extraction film 1 in a case in which the second scattering degree is greater than the first scattering degree. In addition, the reflectivity of the light extraction film 1 in a case in which the first scattering degree due to the first scattering is greater than the second scattering degree due to the second scattering is less than that of the light extraction film 1 in a case in which the second scattering degree is greater than the first scattering degree.

According to an embodiment, when the first scattering degree is greater than the second scattering degree, the light transmittance of the light extraction film 1 may be 70% or greater. When the second scattering degree is greater than the first scattering degree, the light transmittance of the light extraction film 1 may be less than 70%.

Therefore, the luminance of the third light L3 when the first scattering degree is greater than the second scattering degree may be higher than the luminance of the third light L3 when the second scattering degree is greater than the first scattering degree.

According to an embodiment, when the first scattering degree is greater than the second scattering degree, the light reflectivity of the light extraction film 1 may be less than 20%. When the second scattering degree is greater than the first scattering degree, the light reflectivity of the light extraction film 1 may be 20% or greater.

Therefore, the luminance of the fourth light L4 in a case in which the second scattering degree is greater than the first scattering degree may be higher than the luminance of the fourth light L4 in a case in which the first scattering degree is greater than the second scattering degree.

As described above, the luminance of light emitted in the first direction D1 and the second direction D2 from the light-emitting device 20 may be adjusted by adjusting the first scattering degree and the second scattering degree of the light extraction film 1.

That is, when the light extraction film 1 in which the first scattering degree is greater than the second scattering degree is used, the luminance in the first direction D1 may be set to be greater as compared with the light extraction film 1 in which the second scattering degree is greater than the first scattering degree.

Selectively, when the light extraction film 1 in which the second scattering degree is greater than the first scattering degree is used, the luminance in the second direction D2 may be set to be greater than that in a case where the light extraction film 1 is used in which the first scattering degree is greater than the second scattering degree.

Also, the both-side light-emitting lighting device 2 as above may be implemented as a transparent lighting device including the light-emitting device 20 through which external light transmits. In this case, the first light L1 and the third light L3 are radiated in the first direction D1 and the second light L2 and the fourth light L4 are radiated in the second direction D2, and thus, the both-side transparent lighting device may be implemented. Selectively, when the light is not radiated in the first direction D1 and/or the second direction D2, a user may observe an object across because the external light transmits through the light-emitting device 20. In addition, because the luminance in the first direction D1 and/or the second direction D2 may be set as described above, different luminous effects may be implemented in opposite directions.

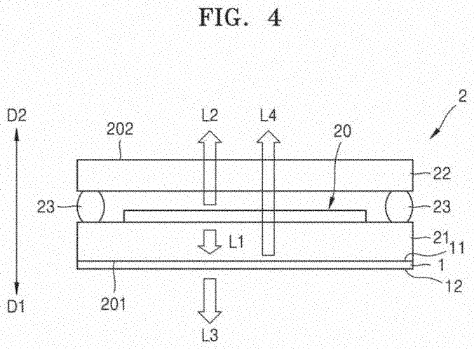

FIG. 4 is a schematic cross-sectional view of the both-side light-emitting lighting device 2 in detail according to another embodiment.

According to the embodiment of FIG. 4, an organic light-emitting unit 24 may be used as the light-emitting device 20. Referring to FIG. 4, the both-side light-emitting lighting device 2 may include a substrate 21 and an encapsulation member 22 facing each other, and the organic light-emitting unit 24 located between the substrate 21 and the encapsulation member 22. The substrate 21 and the encapsulation member 22 may be coupled to each other and may block the organic light-emitting unit 24 disposed therebetween against the external air to encapsulate the organic light-emitting unit 24. According to the embodiment shown in FIG. 4, the encapsulation member 22 is formed in the form of a substrate and may be coupled to the substrate 21 via a sealant 23 at an edge thereof. However, one or more embodiments are not limited thereto, that is, the encapsulation member 22 may include a thin film structure including at least one film, and in this case, the encapsulation member 22 may be formed on the substrate 21 to cover the organic light-emitting unit 24.

According to the embodiment shown in FIG. 4, the light emitted from the organic light-emitting unit 24 may include the first light L1 emitted in a direction toward the substrate 21 and the second light L2 emitted in a direction toward the encapsulation member 22.

The light extraction film 1 according to the above-described embodiments may be coupled to an external surface of the substrate 21. In this case, the light extraction film 1 may be located such that the first surface 11 faces the substrate 21.

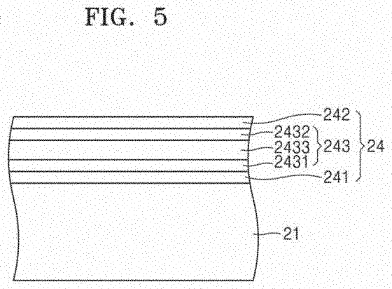

The organic light-emitting unit 24 may include an organic light-emitting device emitting white light, and as shown in FIG. 5, may include a first electrode 241 formed on the substrate 21, a second electrode 242 facing the first electrode 241, and an organic layer 243 disposed between the first electrode 241 and the second electrode 242.

The first electrode 241 and the second electrode 242 may respectively act as an anode and a cathode, or vice versa.

The first electrode 241 may include a conductor having a large work function when acting as an anode, and may include a conductor having a small work function when acting as a cathode. The second electrode 242 may include a conductor having a small work function when acting as a cathode, and may include a conductor having a large work function when acting as an anode. The conductor having a large work function may include a transparent conductive oxide such as ITO, In₂O₃, ZnO, IZO, etc., or noble metal such as Au. The conductor having a small work function may include Ag, Al, Mg, Li, Ca, LiF/Ca, LiF/Al, etc.

In the both-side light-emitting structure shown in FIG. 5, the first electrode 241 and the second electrode 242 may include a light transmitting body.

To this end, when the first electrode 241 acts as an anode, the first electrode 241 may be formed by forming a film of ITO, IZO, ZnO, In₂O₃, etc. having a large work function. In addition, when the first electrode 241 acts as a cathode, a thin semi-transmissive film may be formed by using Ag, Al, Mg, Li, Ca, LiF/Ca, LiF/Al, etc. each having a small work function.

When the second electrode 242 acts as a cathode, the second electrode 242 may be formed to be a semi-transmissive film by using metal such as Li, Ca, LiF/Ca, LiF/Al, Al, Mg, Ag, etc. having a small work function. When the second electrode 242 acts as an anode, the second electrode 242 may be formed by forming a film using ITO, IZO, ZnO, In₂O₃, etc.

The organic layer 243 may include a first organic layer 2431 and a second organic layer 2432, and an emission layer 2433 disposed between the first and second organic layers 2431 and 2432.

The first organic layer 2431 and the second organic layer 2432 accelerate flows of holes and electrons from the anode and the cathode. When the first electrode 241 is an anode, the first organic layer 2431 may include hole injection/transport layers and/or an electron block layer, and the second organic layer 2432 may include electron injection/transport layers and/or a hole block layer. In addition, when the first electrode 241 is a cathode, the first organic layer 2431 may include electron injection/transport layers and/or a hole block layer, and the second organic layer 2432 may include hole injection/transport layers and/or an electron block layer.

The emission layer 2433 may use a single organic compound material capable of emitting white light or may be formed by stacking two or more organic emission layers of different colors.

When the emission layer 2433 is formed by stacking two or more organic emission layers, a red emission layer, a green emission layer, and a blue emission layer may be sequentially stacked or a sky blue emission layer may be stacked on a mixture layer of red and blue.

Methods of implementing white light emission may be applied variously.

The organic light-emitting unit 24 as described above may include a plurality of pixels, but is not limited thereto. In an embodiment, the organic light-emitting unit 24 may be provided as a surface emission type including a single pixel.

Also, selectively in the organic light-emitting unit 24, intervals between the pixels may be transparent, and accordingly, when the light is not emitted, the organic light-emitting unit 24 may be used as a transparent member through which the light passes.

In the both-side light-emitting lighting device 2, the light extraction film 1 may improve light extraction efficiency of the light emitted from the organic light-emitting unit 24 as described above, may obtain a uniform white illumination effect, and may improve power efficiency.

Such above both-side light-emitting lighting device 2 may be manufactured by directly forming the base material 101 of the light extraction film 1 as shown in FIG. 1 on a surface of a base, e.g., the substrate 21 or the encapsulation member 22. However, one or more embodiments are not limited thereto, the light extraction film 1 shown in FIG. 1 may be attached to the substrate 21 or the encapsulation member 22 by using a separate adhesive member and/or a bonding method. Also, the base 100 of the light extraction film 1 shown in FIG. 2 may be attached to the substrate 21 or the encapsulation member 22 by using a separate adhesive member and/or a bonding method.

In the embodiment shown in FIG. 4, a bottom surface of the substrate 21 may be the first light-outputting surface 201 and an upper surface of the encapsulation member 22 may be the second light-outputting surface 202, but one or more embodiments are not limited thereto. In an embodiment, the bottom surface of the substrate 21 may be the second light-outputting surface 202 and the upper surface of the encapsulation member 22 may be the first light-outputting surface 201.

The light extraction film 1 according to a detailed embodiment is as follows.

A coating composition solution is prepared.

According to an embodiment, the coating composition liquid may include colorless polyamic acid.

The coating composition liquid may be fabricated by mixing 4,4′-oxydiphthalic anhydride and 2,2-bis[4-(4-aminophenoxy)phenyl] hexafluoropropane in a DMAc solvent in a 1:1 molar ratio, stirring the mixture for 24 hours, and then diluting the mixture with 3 wt % DMAc solvent.

Next, the coating composition liquid is coated on a base. The base may be the base 100 as shown in FIG. 2, but one or more embodiments are not limited thereto, that is, the base may be the substrate 21 and/or the encapsulation member 22 shown in FIG. 4.

The base coated with the coating composition liquid is loaded in a pore-forming solvent.

The pore-forming solvent may include polar protic solvents and may include alcohol.

100% of de-ionized water (DIW) is used as the pore-forming solvent according to a first embodiment. 100% ethanol is used as the pore-forming solvent according to a second embodiment.

The first and second embodiments formed as above undergo a thermal drying process at a temperature of 170° C. to form a polyimide-based base material 101.

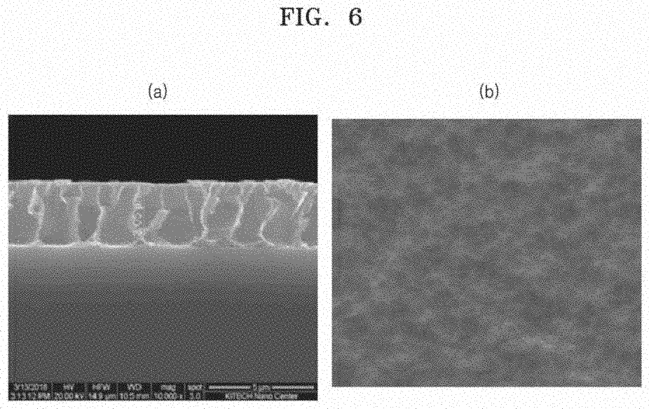

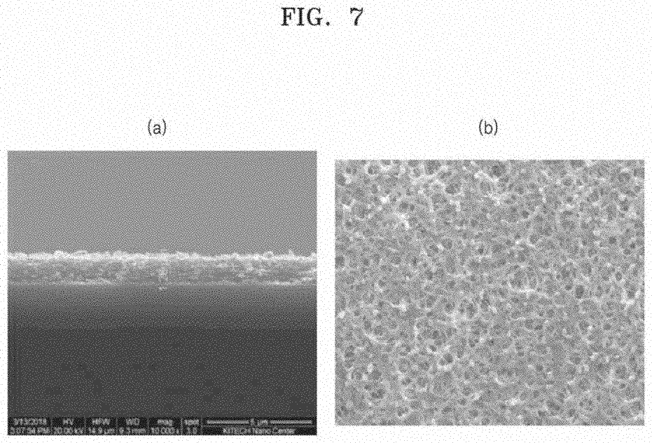

FIG. 6 shows a cross-sectional SEM photograph (a) and a surface SEM photograph (b) of the first embodiment, and FIG. 7 shows a cross-sectional SEM photograph (a) and a surface SEM photograph (b) of the second embodiment.

The formed film, e.g., the base material, had a thickness of 3.05 μm in the first embodiment and 1.28 μm in the second embodiment. As described above, it is identified that the film thickness in the first embodiment is greater than that of the second embodiment, with respect to the film having the same composition.

In the formed pores, a largest pore size (based on longer side) is about 3 μm in the first embodiment and is about 1.3 μm in the second embodiment. It is identified that the pore size of the first embodiment is noticeably larger than that of the second embodiment.

The surface roughness (based on rms) is 3.6 nm according to the first embodiment and is 68 nm according to the second embodiment. It is identified that the surface roughness of the second embodiment is noticeably greater than that of the first embodiment.

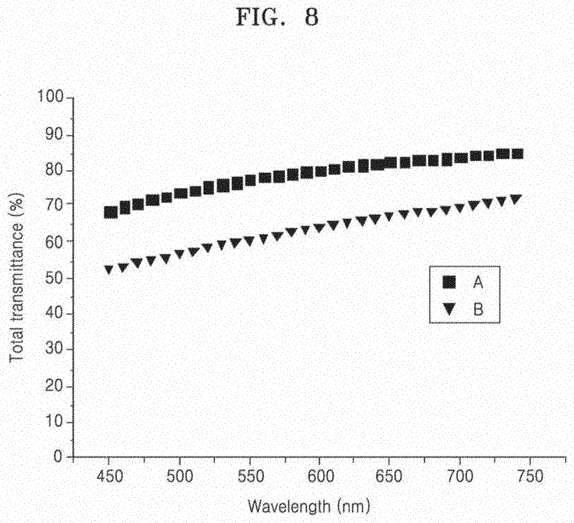

FIG. 8 shows a total transmittance according to a wavelength band of a visible ray area according to the first embodiment (A) and the second embodiment (B). As shown in FIG. 8, the first embodiment (A) shows higher total transmittance and the second embodiment (B) shows lower total transmittance.

According to the first embodiment (A), an average total transmittance is about 74%. Here, an average total reflectivity is 15% in the first embodiment (A).

According to the second embodiment (B), an average total transmittance is about 59%. Here, an average total reflectivity is 26% in the second embodiment (B).

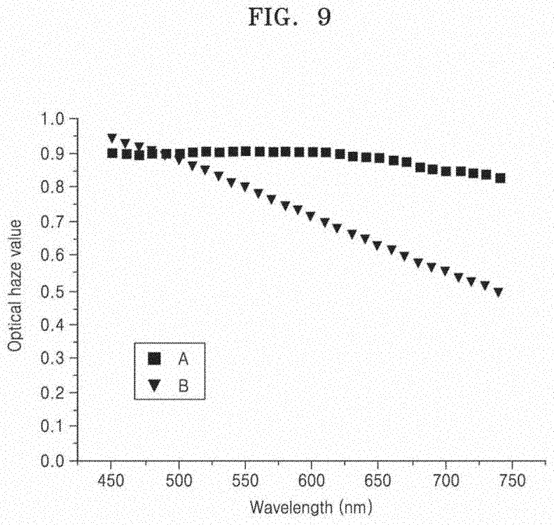

FIG. 9 shows an optical haze value according to a wavelength band of a visible ray region according to the first embodiment (A) and the second embodiment (B).

As shown in FIG. 9, the optical haze value according to the first embodiment (A) decreases with a gentle angle as the wavelength increases, and the optical haze value according to the second embodiment (B) decreases with the sharpest angle as the wavelength increases. Accordingly, the average total optical haze value is lower in the second embodiment (B) than in the first embodiment (A). However, in each case, the average optical haze value of about 80% or greater is shown.

The light extraction film formed as above is installed on the both-side light-emitting lighting device 2 as shown in FIG. 3 and/or FIG. 4. In the structure of FIG. 4, a glass of 700 μm is used as the substrate 21, the first electrode 241 includes 150 nm of ITO, and the second electrode 242 includes 20 nm of aluminum. The first organic layer 2431 includes a stack structure of MoO3 1.5 nm and CBP 45 nm, and the second organic layer 2432 includes a stack structure of TPBi 20 nm, Bphen 45 nm, and Cs2O3 1.5 nm. The emission layer 2433 includes CBP: Ir(ppy)2(acac) of 15 nm.

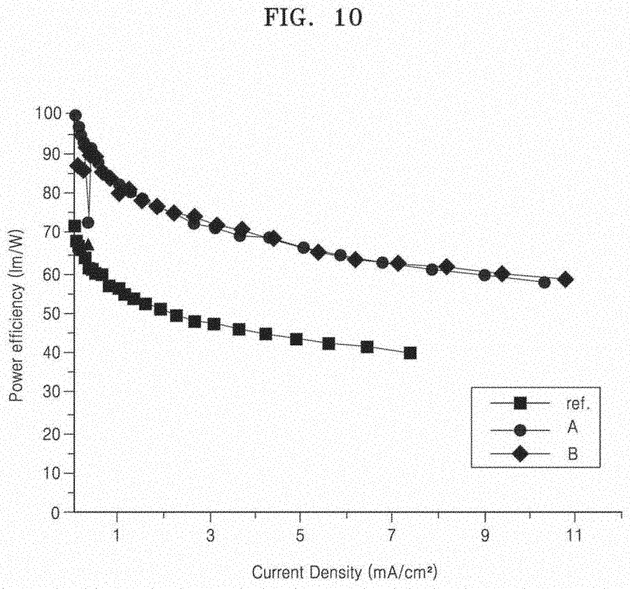

FIG. 10 shows a comparison among power efficiencies of the both-side light-emitting lighting devices on which the first embodiment (A) and the second embodiment (B) are formed, and of a comparative example (ref). The comparative example (ref) does not use the light extraction film.

As shown in FIG. 10, the first embodiment (A) and the second embodiment (B) have much excellent power efficiencies as compared with the comparative example (ref).

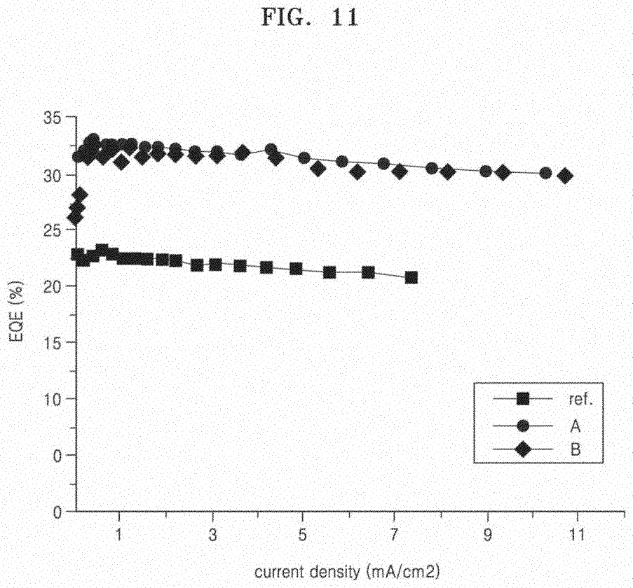

FIG. 11 shows a comparison among external quantum efficiencies (EQE) in the first embodiment (A), the second embodiment (B), and the comparative example (ref). As shown in FIG. 11, the first embodiment (A) and the second embodiment (B) have much higher external quantum efficiencies than the comparative example (ref).

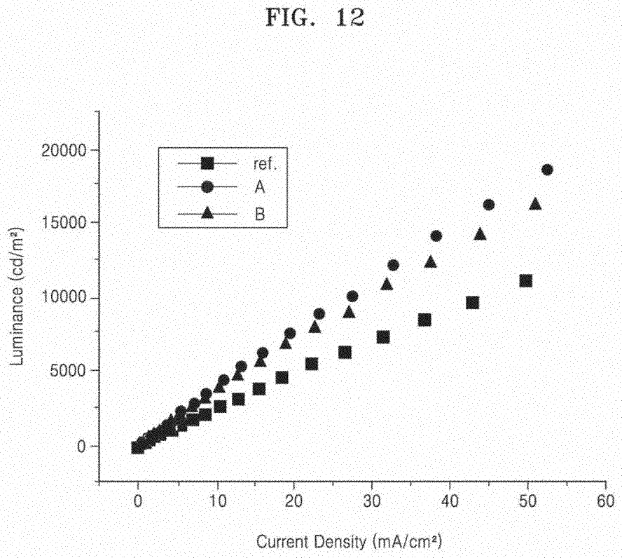

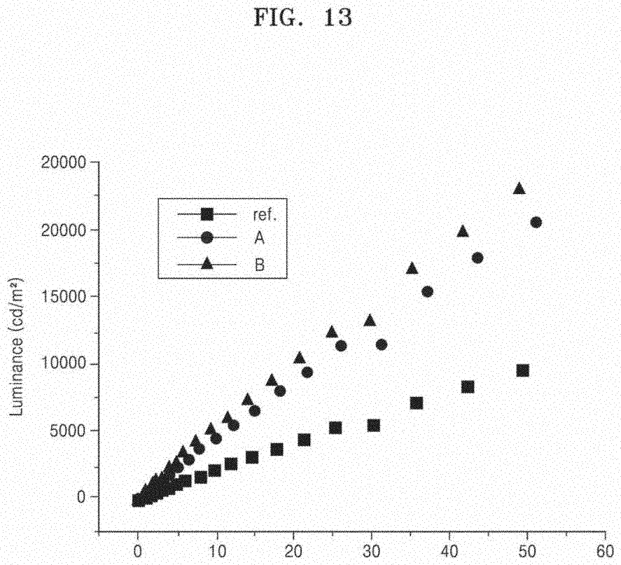

FIG. 12 is a diagram showing a change in a luminance in the first direction D1 according to a current change in the first embodiment (A), the second embodiment (B), and the comparative example (ref). FIG. 13 is a diagram showing a change in a luminance in the second direction D2 according to a current change in the first embodiment (A), the second embodiment (B), and the comparative example (ref).

As shown in FIGS. 12 and 13, the first embodiment (A) and the second embodiment (B) show higher luminance as compared with the comparative example (ref). In particular, the first embodiment (A) and the second embodiment (B) show higher luminance as compared with the comparative example even in the second direction D2 in which the light extraction film 1 is not attached.

In the first direction D1, the first embodiment (A) has higher luminance than that of the second embodiment (B). In the second direction D2, the second embodiment (B) has higher luminance than that of the first embodiment (A).

The first embodiment (A) described above may correspond to a case in which the first scattering degree due to the first scattering is greater than the second scattering degree due to the second scattering. In addition, the second embodiment (B) corresponds to a case in which the second scattering degree due to the second scattering is greater than the first scattering degree due to the first scattering. As described above, although the first embodiment (A) has superior optical characteristics in the first direction D1, the second embodiment (B) may have superior optical characteristics in the second direction D2. Thus, when implementing the both-side light-emitting lighting device, the emitting luminance in opposite directions may be adjusted as desired.

While the present invention has been particularly shown and described with reference to exemplary embodiments thereof, it will be understood by those of ordinary skill in the art that various changes in form and details may be made therein without departing from the spirit and scope as defined by the following claims. Therefore, the scope sought to be protected of the present invention shall be defined by the appended claims.

### INDUSTRIAL APPLICABILITY

A both-side light-emitting lighting device according to the present invention may be used in a transparent lighting device through which external light may transmit. In this case, the light-emitting efficiency and luminance adjustment in both directions may be achieved, and thus, lighting effect may be further improved.

1. A both-side light-emitting lighting device comprising:
a first light-outputting surface;
a second light-outputting surface facing the first light-outputting surface;
a light-emitting device located between the first light-outputting surface and the second light-outputting surface, emitting first light in a direction toward the first light-outputting surface, and emitting second light in a direction toward the second light-outputting surface; and
a light extraction film located on the first light-outputting surface and comprising a base material having a first surface and a second surface facing each other so that the first light enters through the first surface and exits through the second surface, and a plurality of pores irregularly distributed in the base material, wherein
the base material scatters the first light transmitting through the base material, scattering of the light comprises a first scattering caused by pore particles and a second scattering caused by at least one of the first surface and the second surface, and the base material is provided such that a first scattering degree due to the first scattering and a second scattering degree due to the second scattering are different relative to each other.

2. The both-side light-emitting lighting device of claim 1, wherein, when the first scattering degree due to the first scattering is greater than the second scattering degree due to the second scattering, a light transmittance of the base material is 70% or greater.

3. The both-side light-emitting lighting device of claim 1, wherein, when the second scattering degree due to the second scattering is greater than the first scattering degree due to the first scattering, a light transmittance of the base material is less than 70%.

4. The both-side light-emitting lighting device of claim 1, wherein, when the first scattering degree due to the first scattering is greater than the second scattering degree due to the second scattering, a light reflectivity of the base material is less than 20%.

5. The both-side light-emitting lighting device of claim 1, wherein, when the second scattering degree due to the second scattering is greater than the first scattering degree due to the first scattering, a light reflectivity of the base material is 20% or greater.

6. The both-side light-emitting lighting device of claim 1, wherein, when the first scattering degree due to the first scattering is greater than the second scattering degree due to the second scattering, the pores each have a first diameter, when the second scattering degree due to the second scattering is greater than the first scattering due to the first scattering, the pores each have a second diameter, and the first diameter is greater than the second diameter.

7. The both-side light-emitting lighting device of claim 1, wherein, when the first scattering degree due to the first scattering is greater than the second scattering degree due to the second scattering, at least one of the first surface and the second surface has a first roughness, when the second scattering degree due to the second scattering is greater than the first scattering degree due to the first scattering, at least one of the first surface and the second surface has a second roughness, and the second roughness is greater than the first roughness.
